(19) United States
(12) Patent Application Publication
(10) Pub. No.: US 2024/0420998 A1
(43) Pub. Date: Dec. 19, 2024

(54) Reduction of Air Gaps in FinFET Structures

(71) Applicant: Applied Material, Inc., Santa Clara, CA (US)

(72) Inventors: Joni Oskari Raisanen, Tempe, AZ (US); Kunal Bhatnagar, Chandler, AZ (US)

(73) Assignee: Applied Material, Inc., Santa Clara, CA (US)

(21) Appl. No.: 18/209,037

(22) Filed: Jun. 13, 2023

(51) Int. Cl. H01L 21/768; H01L 21/8238; H01L 27/092

(52) U.S. Cl. CPC H01L 21/76847; H01L 21/823821; H01L 27/0924

(57) ABSTRACT

Methods of forming transistors, e.g., FinFETs, are described. A conformal liner layer is formed in a trench. A metal nitride material is introduced in regular or semi-regular intervals during a metal gap fill of a trench structure to prevent the formation of voids (air gaps) within the structure. The metal nitride material and the metal gap fill material may be deposited by atomic layer deposition methods.

### TECHNICAL FIELD

Embodiments of the present disclosure pertain to the field of semiconductor devices and semiconductor device manufacturing. More particularly, embodiments of the disclosure relate to methods of reducing airgaps during a gap fill process.

### BACKGROUND

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

The transistor is a key component of most integrated circuits. Since the drive current, and therefore speed, of a transistor is proportional to the gate width of the transistor, faster transistors generally require larger gate width. Thus, there is a trade-off between transistor size and speed, and “fin” field-effect transistors (finFETs) have been developed to address the conflicting goals of a transistor having maximum drive current and minimum size. FinFETs are characterized by a fin-shaped channel region that greatly increases the size of the transistor without significantly increasing the footprint of the transistor and are now being applied in many integrated circuits. FinFETs, however, have their own drawbacks.

As the feature sizes of transistor devices continue to shrink to achieve greater circuit density and higher performance, there is a need to improve transistor device structure and to reduce contact resistance. Examples of transistor device structures include a planar structure, a fin field effect transistor (finFET) structure, and a gate all around (GAA) structure. Logic gate performance is related to the characteristics of the materials used as well as the thickness and area of the structural layers. As some gate characteristics are adjusted to accommodate device scaling, however, challenges arise.

As the semiconductor manufacturing industry moves into advanced modes below the 2 nm node, there is a desire to improve speed and drive current of devices through reduction of trench variations. Accordingly, there is a need for improved methods of forming semiconductor devices, such as FinFETs.

### SUMMARY

One or more embodiments of the disclosure are directed to methods of forming a transistor. In one or more embodiments, the method comprises: depositing a liner layer on a substrate, the substrate comprising a plurality of features thereon; and performing a process cycle comprising depositing a metal gap fill material on the liner layer and depositing a metal material on the metal gap fill material.

Other embodiments of the disclosure are directed to a method of forming a FinFET. In one or more embodiments, the method comprises: exposing a substrate having at least one feature thereon to a first titanium precursor and a nitrogen-containing reactant to form a titanium silicon nitride liner; and performing a process cycle comprising exposing the substrate to a first molybdenum precursor and a reactant to form a bulk molybdenum film and alternatingly exposing the substrate to a second titanium precursor and a nitrogen-containing reactant to form titanium nitride (TiN) within the bulk molybdenum film.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a process flow diagram of a method according to one or more embodiments;

FIG. 2 illustrates a cross-section view of a device according to one or more embodiments;

FIG. 3 illustrates a cross-section view of a device according to one or more embodiments;

FIG. 4 illustrates a cross-section view of a device according to one or more embodiments;

FIG. 5 illustrates a cross-section view of a device according to one or more embodiments; and

FIG. 6 illustrates a cross-section view of a device according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates.

According to one or more embodiments, the term “on”, with respect to a film or a layer of a film, includes the film or layer being directly on a surface, for example, a substrate surface, as well as there being one or more underlayers between the film or layer and the surface, for example the substrate surface. Thus, in one or more embodiments, the phrase “on the substrate surface” is intended to include one or more underlayers. In other embodiments, the phrase “directly on” refers to a layer or a film that is in contact with a surface, for example, a substrate surface, with no intervening layers. Thus, the phrase “a layer directly on the substrate surface” refers to a layer in direct contact with the substrate surface with no layers in between.

As used in this specification and the appended claims, the terms “precursor,” “reactant,” “reactive gas” and the like are used interchangeably to refer to any gaseous species that can react with the substrate surface.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A, e.g., aluminum precursor) is pulsed into the reaction zone followed by a first time delay. Next, a second precursor or compound B (e.g., oxidant) is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

As used herein, “chemical vapor deposition” refers to a process in which a substrate surface is exposed to precursors and/or co-reagents simultaneous or substantially simultaneously. As used herein, “substantially simultaneously” refers to either co-flow or where there is overlap for a majority of exposures of the precursors.

As used herein throughout the specification, “substantially simultaneously” means that most of the duration of the first reactive compound exposure overlaps with the second reactive compound exposure.

As used herein, the term “purging” includes any suitable purge process that removes unreacted precursor, reaction products and by-products from the process region. The suitable purge process includes moving the substrate through a gas curtain to a portion or sector of the processing region that contains none or substantially none of the reactant. In one or more embodiments, purging the processing chamber comprises applying a vacuum. In some embodiments, purging the processing region comprises flowing a purge gas over the substrate. In some embodiments, the purge process comprises flowing an inert gas. In one or more embodiments, the purge gas is selected from one or more of nitrogen (N₂), helium (He), and argon (Ar). In some embodiments, the purging the substrate surface or the reaction chamber may occur for a time duration in a range of from 0.2 seconds to 30 seconds, from 0.2 seconds to 10 seconds, from 0.2 seconds to 5 seconds, from 0.5 seconds to 30 seconds, from 0.5 seconds to 10 seconds, from 0.5 seconds to 5 seconds, from 1 seconds to 30 seconds, from 1 seconds to 10 seconds, from 1 seconds to 5 seconds, from 5 seconds to 30 seconds, from 5 seconds to 10 seconds or from 10 seconds to 30 seconds.

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate and exhibit a doping profile suitable for a particular application. The gate is positioned over the channel region and includes a gate dielectric interposed between a gate electrode and the channel region in the substrate.

As used herein, the term “field effect transistor” or “FET” refers to a transistor that uses an electric field to control the electrical behavior of the device. Enhancement mode field effect transistors generally display very high input impedance at low temperatures. The conductivity between the drain and source terminals is controlled by an electric field in the device, which is generated by a voltage difference between the body and the gate of the device. The FET's three terminals are source(S), through which the carriers enter the channel; drain (D), through which the carriers leave the channel; and gate (G), the terminal that modulates the channel conductivity. Conventionally, current entering the channel at the source(S) is designated Is and current entering the channel at the drain (D) is designated ID. Drain-to-source voltage is designated VDs. By applying voltage to gate (G), the current entering the channel at the drain (i.e., ID) can be controlled.

The metal-oxide-semiconductor field-effect transistor (MOSFET) is a type of field-effect transistor (FET). It has an insulated gate, whose voltage determines the conductivity of the device. This ability to change conductivity with the amount of applied voltage is used for amplifying or switching electronic signals. A MOSFET is based on the modulation of charge concentration by a metal-oxide-semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both of the same type, and of opposite type to the body region. The source and drain (unlike the body) are highly doped as signified by a “+” sign after the type of doping.

If the MOSFET is an n-channel or nMOS FET, then the source and drain are n+ regions and the body is a p region. If the MOSFET is a p-channel or pMOS FET, then the source and drain are p+ regions and the body is a n region. The source is so named because it is the source of the charge carriers (electrons for n-channel, holes for p-channel) that flow through the channel; similarly, the drain is where the charge carriers leave the channel.

As used herein, the term “fin field-effect transistor (FinFET)” refers to a MOSFET transistor built on a substrate where the gate is placed on two or three sides of the channel, forming a double- or triple-gate structure. FinFET devices have been given the generic name FinFETs because the channel region forms a “fin” on the substrate. FinFET devices have fast switching times and high current density.

As used herein, the term “dynamic random-access memory” or “DRAM” refers to a memory cell that stores a datum bit by storing a packet of charge (i.e., a binary one), or no charge (i.e., a binary zero) on a capacitor. The charge is gated onto the capacitor via an access transistor and sensed by turning on the same transistor and looking at the voltage perturbation created by dumping the charge packet on the interconnect line on the transistor output. Thus, a single DRAM cell is made of one transistor and one capacitor. The DRAM device is formed of an array of DRAM cells. The rows on access transistors are linked by word lines, and the transistor inputs/outputs are linked by bit lines. Historically, DRAM capacitors have evolved from planar polysilicon-oxide-substrate plate capacitors to 3-D structures which have diverged into “stack” capacitors with both plates above the substrate, and “trench” capacitors using an etched cavity in the substrate as the common plate.

Current transistor processes, e.g., DRAM buried word line (bWL) processes, involve a liner and metal (e.g., tungsten (W)) stacks. Due to the poor adhesion between metal and trench structures, however, voiding and delamination of the metal fill is often observed during high-temperature post anneal treatments. Additionally, during subsequent metal etching, voids can cause trench-to-trench variations. Such voids and delamination are undesired because it will cause poor electrical contact and device yield loss. Voids and delamination also contribute to an increase in stack resistance. Accordingly, embodiments of the present disclosure relate to enhancing gap fill performance so as to advantageously reduce voiding while maintaining a high metal percentage within the trench. This should provide lower resistance than previous approaches. In one or more embodiments, fewer process steps are required.

The selection of metal to be used as a gate electrode can greatly impact the performance of the device. Without intending to be bound by theory, it is believed that the use of low resistance metals advantageously provides transistor structures with reduced resistance. When exposed to the thermal process requirements used in manufacturing transistors, however, these materials are often found to delaminate from the surface. The delamination can impact final array resistance and cause reliability issues.

Current approaches for filling semiconductor structures are unable to have low-void fill when using molybdenum (Mo). Resistance is elevated due to voiding, and poor electrical contact leads to device yield loss. During metal etch back, voids cause trench-to-trench variations. One or more embodiments of the disclosure are directed to methods for forming semiconductor devices. Some embodiments of the disclosure incorporate a thin titanium nitride (TiN) film introduced in regular or semi-regular intervals during a molybdenum fill of a FinFET structure to prevent the formation of voids (air gaps) within the structure. In some embodiments, the cycle of alternatingly depositing a gap fill material a thin metal material film can be repeated such that multiple thin layers of metal material are deposited and laminated within the gap fill material.

One or more embodiments reduce voiding while maintaining a high metal percentage within the trench of the semiconductor device. In one or more embodiments, this provides lower resistance than previous approaches.

Further embodiments of the disclosure are directed to memory transistors (e.g., DRAM) with a thin titanium nitride (TiN) film introduced in regular or semi-regular intervals during a molybdenum fill.

The embodiments of the disclosure are described by way of the Figures, which illustrate processes and substrates in accordance with one or more embodiments of the disclosure. The processes, schemes, and resulting substrates shown are merely illustrative of the disclosed processes, and the skilled artisan will recognize that the disclosed processes are not limited to the illustrated applications.

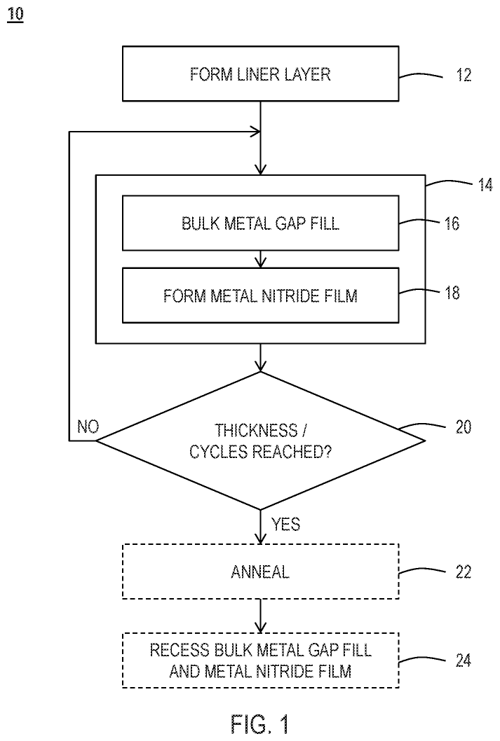

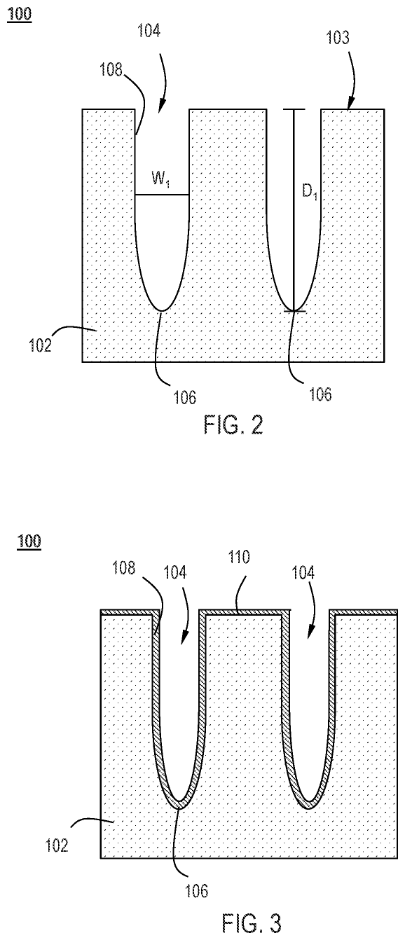

FIG. 1 illustrates a process flow diagram of a method according to one or more embodiments of the present disclosure. FIGS. 2-5 illustrate cross-sectional views of a device being processed according to the method of FIG. 1.

With reference to FIG. 1, one or more embodiments of the disclosure are directed to a method 10 of depositing a film. The method illustrated in FIG. 1 is representative of an atomic layer deposition (ALD) process in which the substrate or substrate surface is exposed sequentially to the reactive gases in a manner that prevents or minimizes gas phase reactions of the reactive gases. In some embodiments, the method comprises a chemical vapor deposition (CVD) process in which the reactive gases are mixed in the processing chamber to allow gas phase reactions of the reactive gases and deposition of the thin film.

In one or more embodiments, the method 10 at operation 12 includes forming a conformal liner layer. The liner layer may be formed by any suitable means including, but not limited to ALD and CVD. At operation 14, the method includes a cycle of forming a metal nitride film and a bulk metal gap fill. In one or more embodiments, a thin metal nitride film (operation 16) is introduced in regular or semi-regular intervals during a metal gap fill (operation 18) of a trench structure to prevent the formation of voids (air gaps) within the structure. At decision point 20, the thickness of the deposited film, or number of cycles of metal nitride film and bulk metal gap fill is considered. If the deposited film has reached a predetermined thickness or a predetermined number of process cycles have been performed, the method 10 moves to operation 22, where the substrate is optionally annealed.

Referring to FIG. 2, a substrate 102 is provided having a plurality of trenches 104 therein. As used in this specification and the appended claims, the term “provided” means that the substrate is made available for processing (e.g., positioned in a processing chamber). The trenches 104 form a recessed channel. In one or more embodiments, the trenches have a bottom 106 and at least one sidewall 108. The plurality of trenches 104 may be formed so as to have a width within a range of about 10 to about 100 nm, including, but not limited to a range of about 10 nm to about 80 nm, about 10 nm to about 70 nm, about 10 nm to about 60 nm, about 10 nm to about 50 nm, or about 10 nm to about 40 nm. As will be recognized by one of skill in the art, the width of the plurality of trenches 104 is defined by a distance W₁ from one sidewall 108 to another sidewall 108.

The plurality of trenches 104 may be formed so as to have a depth within a range of about 120 nm to about 250 nm, including, but not limited to a range of about 120 nm to about 150 nm, about 150 nm to about 200 nm, about 200 nm to about 250 nm, about 120 nm to about 200 nm, or about 150 nm to about 250 nm. As will be recognized by one of skill in the art, the depth of the plurality of trenches 104 is defined by the distance D₁ from the substrate surface 103 to the bottom 106 of the plurality of trenches 104.

In order to form the plurality of trenches 104, a buffer insulating layer (e.g., a silicon oxide layer, not illustrated) may be formed on the substrate surface 103, and/or a hard mask layer (e.g., a nitride layer, not illustrated) may be formed. Such techniques are well known to those skilled and the art, and, thus, are not illustrated.

With reference to FIG. 1 and FIG. 3, at operation 12, a liner layer 110 is conformally deposited on the substrate 102, on the substrate surface 103 and along the sidewall(s) 108 and bottom 106 of the plurality of trenches 104. As used herein, the term “conformal” means that the liner layer 110 adapts to the contours of the feature or. Conformality of a layer is typically quantified by a ratio of the average thickness of a layer deposited on the sidewalls of a feature to the average thickness of the same deposited layer on the field, or upper surface, of the substrate.

The liner layer 110 may comprise any suitable material. In one or more embodiments, the liner layer 110 comprises one or more of titanium nitride (TiN), tantalum nitride (Ta), and titanium silicon nitride (TiSiN). In specific embodiments, the liner layer comprises titanium silicon nitride (TiSiN).

The liner layer 110 may be formed by any suitable means. In one or more embodiments, the liner layer 110 is formed by atomic layer deposition (ALD). Thus, in one or more embodiments, the liner layer 110 may be formed by soaking the substrate in a solution of a metal precursor, e.g., a titanium precursor. In some embodiments, the metal precursor may comprise a titanium halide selected from one or more of titanium chloride (TiCl₄), titanium fluoride (TiF₄), titanium iodide (TiI₄), titanium bromide (TiBr₄), or a tantalum halide selected from one or more of tantalum chloride (TaCl₄), tantalum fluoride (TaF₄), tantalum iodide (Tal₄), tantalum bromide (TaBr₄). In some embodiments, the substrate may be soaked in the metal precursor for a time period in a range of from greater than 0 seconds to 60 seconds. In some embodiments, the substrate may be soaked in the metal precursor at a pressure in a range of from 3 Torr to 50 Torr and at a temperature in a range of from 300° C. to 600° C. or from 400° C. to 550° C.

The substrate surface or the processing chamber may be optionally purged of the metal precursor. As used in this manner, the term “processing chamber” also includes portions of a processing chamber adjacent to the substrate surface without encompassing the complete interior volume of the processing chamber. For example, in a sector of a spatially separated processing chamber, the portion of the processing chamber adjacent the substrate surface is purged of the molybdenum precursor by any suitable technique including, but not limited to, moving the substrate through a gas curtain to a portion or sector of the processing chamber that contains none or substantially none of the molybdenum precursor. In one or more embodiments, purging the processing chamber comprises applying a vacuum. In some embodiments, purging the processing chamber comprises flowing a purge gas over the substrate. In some embodiments, the portion of the processing chamber refers to a micro-volume or small volume process station within a processing chamber. The term “adjacent” referring to the substrate surface means the physical space next to the surface of the substrate which can provide sufficient space for a surface reaction (e.g., precursor adsorption) to occur. In one or more embodiments, the purge gas is selected from one or more of nitrogen (N₂), helium (He), and argon (Ar).

In one or more embodiments, the substrate may then be exposed to a reactant to form the liner layer 110 on the substrate and conformally deposited on the plurality of features 104. The substrate surface or the processing chamber may be optionally purged of the reactant.

In one or more embodiments, the liner layer 110 has a thickness in a range of from about 1 Å to about 20 Å, or in a range of from 1 Å to 15 Å, or in a range of from 1 Å to 10 Å, including about 1 Å, about 2 Å, about 3 Å, about 4 Å, about 5 Å, about 6 Å, about 7 Å, about 8 Å, about 9 Å, about 10 Å, about 11 Å, about 12 Å, about 13 Å, about 14 Å, about 15, about 16 Å, about 17 Å, about 18 Å, about 19 Å, and about 20 Å.

Referring to FIG. 1 and FIGS. 4 and 5, at deposition 14, in one or more embodiments, a metal gap fill material 114 and a metal material 112 are introduced in regular or semi-regular intervals during gap fill of a transistor structure, e.g., FinFET structure, to prevent the formation of voids (air gaps) within plurality of features 104 of the structure 100. The metal material 112 may be in the form of a thin layer. In one or more embodiments, the thin layer of metal material 112 may be conformal.

In some embodiments, the regular or semi-regular intervals during gap fill of a transistor structure may provide a cycle of alternatingly depositing a metal gap fill material 114 and a thin metal material 112 layer. In one or more embodiments, the cycle can be repeated such that multiple thin layers of metal material 112 are deposited and laminated within the metal gap fill material 114.

In one or more embodiments, the introduction of a metal material 112 in regular or semi-regular intervals during gap fill with a metal gap fill material 114 is referred to as the nanolaminate approach. The nanolaminate approach of one or more embodiments allows for a liner layer 110, e.g., TiSiN, to be advantageously used, providing a benefit in interface trap density (Dᵢₜ) and flatband voltage (V_{FB}). Additionally, without intending to be bound by theory, it is thought that the nanolaminate approach of one or more embodiments results in a resistivity benefit due to a greater percentage of material in the structure being a gap fill material 114.

In one or more embodiments, the metal material 112 comprises any suitable metal material or metal nitride material known to the skilled artisan. In one or more embodiments, the metal material 112 comprises one or more of cobalt (Co), titanium (Ti), tungsten (W), tantalum (Ta), molybdenum (Mo), titanium nitride (TiN), tungsten nitride (WN), tantalum nitride (TaN), molybdenum nitride (MoN), TaN/TIN, or WN/TIN. In one or more embodiments, the metal material 112 is selected from the group consisting of titanium (Ti), tungsten (W), tantalum (Ta), molybdenum (Mo), titanium nitride (TiN), tungsten nitride (WN), tantalum nitride (TaN), molybdenum nitride (MoN), TaN/TIN, WN/TIN, and combinations thereof. In one or more embodiments, the metal material 112 comprises titanium nitride.

The metal material 112 may be deposited by any suitable means. In one or more embodiments, the metal material 112 is deposited by atomic layer deposition (ALD). In one or more embodiments, the substrate is exposed to a metal precursor followed by exposure to a reactant to form the metal material 112. The substrate may be exposed to the metal precursor and the reactant sequentially or simultaneously.

In one or more embodiments, the metal material 112 has a thickness in a range of about >0 Å to about 15 Å, including about 1 Å, about 2 Å, about 3 Å, about 4 Å, about 5 Å, about 6 Å, about 7 Å, about 8 Å, about 9 Å, about 10 Å, about 11 Å, about 12 Å, about 13 Å, about 14 Å, and about 15 Å.

With reference to FIG. 1 and FIGS. 4 and 5, at operation 16, a metal gap fill material 114 is deposited in the plurality of trenches 104 on the liner layer 110 and in regular or semi-regular intervals with the metal material 112. The metal gap fill material 114 and the metal material 112 may be deposited simultaneously or alternating. In one or more embodiments, the metal gap fill material 114 is formed by depositing a bulk gap fill using atomic layer deposition (ALD).

In one or more embodiments, the metal gap fill material 114 may comprise any suitable metal known to the skilled artisan. In one or more embodiments, the metal gap fill material 114 comprises one or more of molybdenum (Mo), tungsten (W), cobalt (Co), In specific embodiments, the metal gap fill material 114 comprise molybdenum (Mo).

In one or more embodiments, the metal gap fill material 114 at operation 18 may comprise any suitable gap fill process known to one of skill in the art. In some embodiments, the gap fill process comprises exposing the substrate to a metal precursor and a reactant. In one or more embodiments, the gap fill process comprises exposing the substrate a molybdenum precursor, e.g., molybdenum dichloride dioxide (MoO₂Cl₂), and a reactant, e.g., hydrogen (H₂), to a form a bulk molybdenum film.

The molybdenum precursor can be any suitable molybdenum-containing compound. In one or more embodiments, the molybdenum precursor comprises one or more of molybdenum chloride (MoCl₅), molybdenum fluoride (MoF₆), molybdenum iodide (Mol₆), molybdenum bromide (MoBr₃), molybdenum hexacarbonyl (Mo(CO)₆), molybdenum dichloride dioxide (MoO₂Cl₂), molybdenum oxytetrachloride (MoOCl₄), Tetrakis(dimethylamino) molybdenum (IV), and Bis(tert-butylimido)-bis(dimethylamido) molybdenum. In some embodiments, the substrate (or substrate surface) is exposed to a molybdenum precursor at a pressure in a range of from 10 Torr to 50 Torr and at a temperature in a range of from 400° C. to 550° C.

In some embodiments, the gap fill process of operation 18 may be a bottom-up gap fill. In other embodiments, the gap fill process made be a traditional gap fill process.

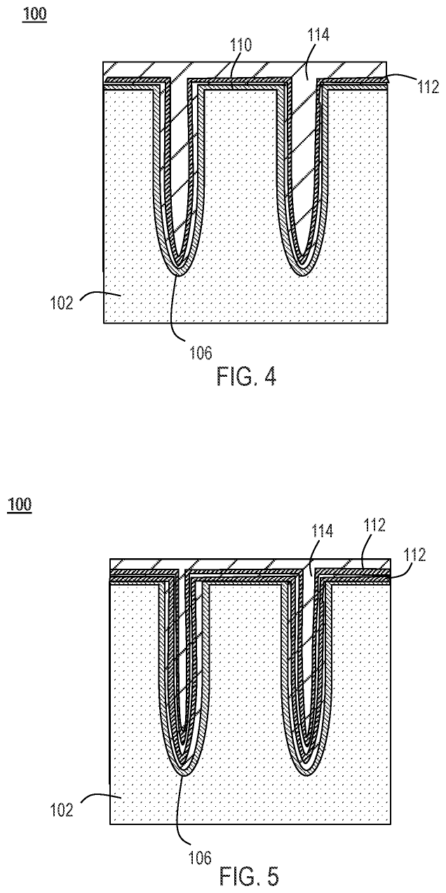

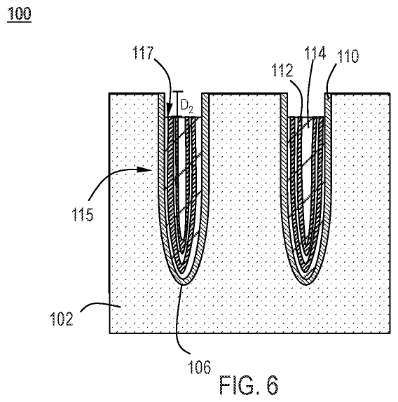

In some embodiments, the thickness T₁ of the metal gap fill material 114 is controlled. In some embodiments, the thickness T₁ of the metal gap fill material 114 is controlled relative to the depth D₁ of the plurality of trenches 104. In some embodiments, the thickness T₁ is greater than or equal to about 90% of the depth D₁ of the plurality of trenches 104. Referring to FIGS. 4 and 5, in some embodiments, the thickness T₁ of the metal gap fill material 114 is in excess of the depth D₁ of the trench 104, an overburden of the metal gap fill material 114 may be formed on the substrate.

Without intending to be bound by theory, it is believed that alternating deposition of the metal material 112 and the metal gap fill material 114 according to the method of one or more embodiments advantageously provides no delamination of the metal gap fill material 114 upon annealing and results in substantially no voids being formed, particularly substantially no voids at the interface between the liner layer 110 and the metal gap fill material 114. In some embodiments, the metal gap fill material 114 has small grains of the metal material 112 contained therein, reducing the percentage of voids present in the metal gap fill material 114. Additionally, it is thought that interrupting the gap fill process of the metal gap fill material 114 with regular or semi-regular deposition of a metal material 112 reduces the grain size of the metal in the metal gap fill material 114, thus also contributing to a reduction in voids. As used in this regard, a material which contains substantially no seam or voids has gaps, seams or voids which occupy less than 2%, less than 1% or less than 0.5% of the volume of the stated material.

With reference to FIG. 1, at decision point 20, the thickness of the deposited film, or number of cycles of metal material 112 and metal gap fill material 114 is considered. If the deposited film has reached a predetermined thickness or a predetermined number of process cycles have been performed, the method 10 moves to the anneal operation 22. If the thickness of the deposited film or the number of process cycles has not reached the predetermined threshold, the method 10 returns to deposition 14 form the metal material 112 and the metal gap fill material 114 and continuing.

In one or more embodiments, after the gap fill process, the substrate is annealed at operation 22. The annealing may comprise any suitable annealing process known to one of skill in the art. In one or more embodiments, annealing is conducted at a temperature in a range of from 600° C. to 1200° C. in an atmosphere of one or more of argon (Ar), nitrogen (N₂), or hydrogen (H₂) gas. In some embodiments, the annealing may be performed in one or more steps.

Referring to FIG. 1 and FIG. 6, at operation 24, in one or more embodiments, the metal gap fill material 114 is recessed (buried) by chemical mechanical polishing (CMP) and an etch back such that the metal gap fill material 114 and the metal material 112 do not protrude beyond the substrate surface 103 (e.g., so that the metal layer 114 is completely buried within the substrate 102).

In one or more embodiments, a buried word line 115 (i.e., the recessed metal gap fill material 114) may be formed. In some embodiments, as illustrated in FIG. 6, the metal material 112 is recessed to the same level as the buried word line 115. The top surface 117 of the buried word line 115 and the metal material 112 is a recess depth or distance D₂ from the substrate surface 103 in the plurality of trenches 104. After formation of the word line 115, processing of the substrate can continue to form a FinFET, e.g., memory device. Such processes are known by the skilled artisan.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below,” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

1. A method of forming a transistor, the method comprising:
depositing a liner layer on a substrate, the substrate comprising a plurality of features thereon; and
performing a process cycle comprising depositing a metal gap fill material on the liner layer and depositing a metal material on the metal gap fill material.

2. The method of claim 1, wherein liner layer comprises one or more of titanium nitride (TiN), tantalum nitride (Ta), and titanium silicon nitride (TiSiN).

3. The method of claim 2, wherein the liner layer comprises titanium silicon nitride (TiSiN).

4. The method of claim 1, wherein the liner layer has a thickness in a range of from about 1 Å to about 20 Å.

5. The method of claim 1, wherein the metal gap fill material comprises one or more of molybdenum (Mo), tungsten (W), and cobalt (Co).

6. The method of claim 5, wherein the metal gap fill material comprises molybdenum (Mo).

7. The method of claim 1, wherein the metal material comprises one or more of cobalt (Co), titanium (Ti), tungsten (W), tantalum (Ta), molybdenum (Mo), titanium nitride (TiN), tungsten nitride (WN), tantalum nitride (TaN), molybdenum nitride (MON), TaN/TIN, or WN/TiN.

8. The method of claim 7, wherein the metal material comprises titanium nitride (TiN).

9. The method of claim 1, wherein the metal material has a thickness in a range of about >0 Å to about 15 Å.

10. The method of claim 1, wherein depositing the metal gap fill material comprises exposing the substrate to a first metal precursor and a first reactant.

11. The method of claim 10, wherein depositing the metal gap fill material comprises exposing the substrate to a molybdenum precursor and hydrogen (H₂) to fill the plurality of features with a bulk molybdenum film.

12. The method of claim 1, wherein depositing the metal material comprises exposing the substrate to a second metal precursor and a reactant.

13. The method of claim 1, further comprising repeating the process cycle to form a metal gap fill material having a thickness greater than or equal to above 90% of a depth of the plurality of features.

14. The method of claim 1, further comprising annealing the substrate wherein there is substantially no delamination of the metal gap fill material, and the metal gap fill material has substantially no voids.

15. The method of claim 14, further comprising recessing a portion of the metal gap fill material and the metal material to form a buried word line.

16. The method of claim 1, wherein the metal material comprises a thin film within the metal gap fill material.

17. The method of claim 16, further comprising repeating the process cycle to form multiple layers of the metal material within the metal gap fill material.

18. A method of forming a FinFET, the method comprising:
exposing a substrate having at least one feature thereon to a first titanium precursor and a nitrogen-containing reactant to form a titanium silicon nitride liner; and
performing a process cycle comprising exposing the substrate to a first molybdenum precursor and a reactant to form a bulk molybdenum film and alternatingly exposing the substrate to a second titanium precursor and a nitrogen-containing reactant to form a titanium nitride (TiN) layer within the bulk molybdenum film.

19. The method of claim 18, wherein the bulk molybdenum film and the titanium nitride (TiN) layer are formed sequentially.

20. The method of claim 18, wherein the bulk molybdenum film and the titanium nitride (TiN) layer are formed simultaneously.
